(19) United States
(12) Patent Application Publication
(10) Pub. No.: US 2012/0161098 A1
(43) Pub. Date: Jun. 28, 2012

(54) SUBSTRATE, MANUFACTURING METHOD OF SUBSTRATE, SEMICONDUCTOR ELEMENT, AND MANUFACTURING METHOD OF SEMICONDUCTOR ELEMENT

(75) Inventors: Hidefumi Hiura, Tokyo (JP); Kazuhito Tsukagoshi, Ibaraki (JP)

(73) Assignee: NEC CORPORATION, Tokyo (JP)

(21) Appl. No.: 13/391,104

(22) PCT Filed: Aug. 20, 2009
(86) PCT No.: PCT/JP2010/064319

§ 371 Date: Feb. 17, 2012

(30) Foreign Application Priority Data
Aug. 20, 2009 (JP) 2009-190948

(51) Int. Cl. H01L 29/02; B82Y 99/00

(52) U.S. Cl. 257/9; 257/E29.002; 977/734

(57) ABSTRACT

A semiconductor device is provided which is produced from a high-quality and large-area graphene substrate and is capable of fully exhibiting superior electronic properties that graphene inherently has. The semiconductor device is capable of realizing increased operation speed, reduced power consumption, and higher degree of integration, and thus is capable of improving the reliability and productivity. Electrical short circuit between a graphene layer (4) and a metal catalyst layer for growth of graphene is prevented by causing the metal catalyst layer to be absorbed as a compound/alloyed layer 5 at the interface between a substrate (1) and an oxide layer (2).

### TECHNICAL FIELD

This invention relates to substrates and semiconductor elements. In particular, the invention relates to substrates comprising unique electronic properties and optical characteristics, and excellent mechanical characteristics and chemical characteristics derived from atomic layer thin films, and thus applicable to next-generation electronics, optoelectronics, and spintronics, and also relates to semiconductor elements using such substrates.

### BACKGROUND ART

The recent information-oriented society is supported by semiconductor elements represented by silicon-based CMOSs (Complementary Metal-Oxide Semiconductors). So far, the silicon semiconductor industry has achieved miniaturization by continuously reducing the limit of processability of microprocessing technologies such as lithography, etching, and deposition technologies from the order of micrometers to several tens of nanometers, and has realized both high integration and high performance. However, the element size is bound to reach an atomic or molecular level in near future, and physical limitation of semiconductor materials such as silicon and existing element structures are pointed out. In order to break such deadlock, there exists a demand for novel element structures based on novel semiconductor materials or novel ideas. Particularly, atomic layer thin films of graphene or the like have recently been attracting attention as a novel semiconductor material having a great potential to respond to this demand. The atomic layer thin films have a potential to realize novel elements capable of providing performances exceeding those of existing elements by utilizing excellent physical properties thereof.

The term “atomic layer thin film” means an ultrathin film having a thickness corresponding to several to a little more than 10 atoms, that is, several nanometer to a little more than 10 nanometers. The atomic layer thin film is ideally a monocrystal film. The most famous and basic one of the atomic layer thin films is graphene. Graphene is a monolayer of graphite which is a layered material consisting only of sp² hybridized carbon, and is stable planar monoatomic layer material. Although the term graphene usually means a monolayer of graphite, it often includes those with two or more layers. Graphene consisting of a single layer is referred to as monolayer graphene, the one consisting of two layers is referred to as bilayer graphene, and the one consisting of three layers is referred to as trilayer graphene, and those consisting of up to about 10 layers are collectively referred to as few-layer graphene. At the same time, those other than the monolayer graphene shall be represented as multilayer graphene. The graphene has a structure of a honeycomb-like pseudo two-dimensional sheet in which regular hexagonal six-carbon rings with a carbon atom at each apex are arranged tightly. The carbon-to-carbon distance is about 1.42 angstroms (0.142 nm), the layer thickness is 3.3 to 3.4 angstroms (0.33 to 0.34 nm) when the base is graphite, and about 10 angstroms (1 nm) when the base is other substrates. The size of the graphene plane can be various. For example, the length of one piece of graphene may assume various sizes from a molecular size of a nanometer order to theoretically an infinite size. Further, the graphene has three axes of symmetry in the plane due its honeycomb structure. Therefore, when the structure is rotated by 120 degrees about a certain point, it will be overlapped with the original structure.

The electronic state of graphene can be described by a Dirac equation in a low energy region. In this respect, graphene presents a marked contrast to other materials than graphene the electronic state of which can be described well by a Schrodinger equation. The electronic energy of graphene has a linear dispersion relation to wave number in the vicinity of the K-point. More specifically, the electronic energy of graphene can be represented by two straight lines having positive and negative slopes corresponding to a conduction band and a valence band. The point where these straight lines intersect is called Dirac point, where electrons of graphene have peculiar electronic properties, behaving as fermions with an effective mass of zero. For this reason, grapheme exhibits a theoretical mobility of 10⁶ cm²V⁻¹s⁻¹ and an actual mobility of 2×10⁵ cm²V⁻¹s⁻¹, both of which are the maximum values in the existing materials. Moreover, graphene is characterized by having low temperature dependency. Graphene is basically a metal or semimetal with a band gap of zero. However, when the size becomes an order of nanometers, the band gap will become wide, and the graphene becomes a semiconductor having a finite band gap, depending on the width and edge structure of the graphene. A bilayer graphene has a band gap of zero when there is no perturbation. However, when such perturbation as to break the mirror symmetry between the two graphene layers, for example an electric field is applied, the graphene will have a finite band gap according to the magnitude of the electric field.

The most basic element utilizing the aforementioned features is a field-effect transistor (FET) using graphene for a channel. The first report on a graphene FET is found in K. S. Novoselov, A. K. Geim, S. V. Morozov, D. Jiang, Y. Zhang, S. V. Dubonos, I. V. Grigorieva, and A. A. Firsov, “Electric Field Effect in Atomically Thin Carbon Films”, Science, 306, 22 October 2004, p 666-669 (Non-Patent Document 1). The FET described in this Non-Patent Document 1 has a structure in which a graphene piece used for a channel is arranged on a highly doped silicon substrate with silicon oxide interposed therebetween, and two gold electrodes are connected to the opposite ends of the graphene piece to provide source and drain electrodes, while the highly doped silicon is used as a back gate electrode. The graphene piece is obtained by using a standard lithography and etching technique to cut out a graphene piece from the surface of highly oriented pyrolytic graphite (HOPG) and a thin piece is peeled off with the use of an adhesive tape to obtain a final graphene piece. The graphene channel of this element has a large width of at least 80 nanometers, no quantum size effect caused by the edge structure does not occur in this metal in the same state as the macro-scale bulk state. The reason why the field effect occurs not in the semiconductor but in the metallic graphene is that the used metallic graphene, consisting of one to several layers, is very thin in the thickness direction, and hence the electric field applied via the gate electrode is able to overwhelm the shielding by carrier in the graphene channel. Since the graphene channel is intentionally not doped, the same number of conduction electrons and electron holes exist as the carrier when the gate voltage is zero and no electric field exists. When the gate voltage is applied in a negative direction, the electrons are depleted and the electron holes are accumulated to perform conduction. Whereas, when the gate voltage is applied in a positive direction, the electron holes are depleted and the electrons are accumulated to perform conduction. This means that while the element exhibits so-called ambipolar conduction, the element is not completely turned off since the electron holes and the electrons cannot be depleted simultaneously. Accordingly, this graphene element does not have high performance from the viewpoint of performance index of typical field-effect transistors. Nevertheless, metallic graphene has attracted attention as an interesting system in the field of pure physics since metallic graphene behaves as ideal and peculiar two-dimensional gas.

At present, graphene elements are mostly manufactured using the existing microprocessing technologies. For example, as described in Non-Patent Document 1, peeled graphene is obtained by a so-called mechanical exfoliation method in which natural graphite or HOPG (Highly Oriented Pyrolytic Graphite) is thinly peeled off with the use of an adhesive tape and the peeled piece is attached onto an appropriate substrate. This method is satisfactory for producing several to several tens of separate elements, for example for the purpose of verifying possible performance of the elements in the laboratory stage. However, the method is not suitable for mass production and hence is virtually impossible to be used industrially. A potential method for mass producing graphene elements is a method in which a microprocessing technology is applied to a substrate carrying a large-area graphene on its surface that is used as a starting material. The method using the graphene substrate as the starting material has an advantage that a microprocessing technology cultivated in the semiconductor industry using silicon substrates can be applied to some extent while there exists limitation in the current state. There are principally two different methods for fabricating a graphene on a substrate. One of them is a method of forming a graphene thin film on a substrate of silicon carbide (SiC), and the other one is a CVD (Chemical Vapor Deposition) method using a metal catalyst. According to the former method as disclosed in Konstantin V. Emtsev, Aaron Bostwick, Karsten Horn, Johannes Jobst, Gary L. Kellogg, Lothar Ley, Jessica L. McChesney, Taisuke Ohta, Sergey A. Reshanov, Jonas Rohrl, Eli Rotenberg, Andreas K. Schmid, Daniel Waldmann, Heiko B. Weber & Thomas Seyller, “Towards wafer-size graphene layers by atmospheric pressure graphitization of silicon carbide”, nature materials, volume 8, March 2009, p 203-207 (Non-Patent Document 2), monocrystal SiC is heated to 1200° C. or higher so that the carbon in the surface of the SiC is once released and then is restructured to epitaxially grow graphene, while the remaining surface silicon combines with oxygen in the heated atmosphere to become volatile SiO or the like and is discharged. Accordingly, only the most superficial part of the SiC substrate is used for formation of graphene, while the other part remains as SiC. The SiC, having a large band gap, serves as an insulator substrate, and, as a result, a graphene substrate comprising graphene formed on the surface of the SiC substrate as the insulator is obtained by thermal treatment of the SiC substrate. A method of manufacturing graphene by the CVD process is described in Japanese Laid-Open Patent Publication No. 2008-50228 (Patent Document 1), Japanese Laid-Open Patent Publication No. 2009-91174 (Patent Document 2), and Japanese Laid-Open Patent Publication No. 2009-107921 (Patent Document 3). The principle of the CVD process is that a hydrocarbon such as methane is thermally decomposed on a metal-monocrystals or metal-film deposited substrate, and then the released carbon is restructured on the metal. In this case, the metal serves as a catalyst, and a transition metal is principally used for this purpose. Although other atomic layer thin films than graphene are also expected to have excellent electronic properties, very few such films are known and, moreover, knowledge about the structure and physical properties thereof is extremely limited. An ALD (Atomic Layer Deposition) process is known as a method of producing an atomic layer thin film. However, this method is applicable to only limited semiconductors and metals, and requires a large-scale system and high cost.

### DISCLOSURE OF THE INVENTION

However, the graphene manufacturing methods as disclosed in Patent Documents 1 to 3 and other currently available techniques have problems as described below.

A first problem is that the substrate used for CVD growth of graphene cannot be used directly for production of elements. This is attributable to the fact that the graphene is entirely in contact with a metal. Even if an element is produced from this material, electric current will flow preferentially through the metal and very little current will flow through the graphene. This is because a metal catalyst is indispensable for CVD growth of large-area graphene, and the graphene grows along the metal surface, whereby the graphene layer is attached so firmly to the metal surface that they cannot be separated from each other.

A second problem resides in that conventional CVD grown graphene has much higher sheet resistance than an ideal graphene, and has very poor mobility. This is attributable to the fact that many lattice defects are introduced in the graphene, structural breaks or wrinkles are generated, or a contaminant inhibiting electron transport adheres to the graphene. This is because, according to a conventional technique, the graphene must be once peeled off from a substrate for growth by dissolving a catalyst metal with an etchant such as an acid or iron oxide solution and then transferred to another substrate in order to produce an element. The graphene inevitably suffers from structural break or contamination with charge or magnetic contaminants during this transfer.

A third problem resides in that fabrication of low-cost and versatile atomic layer thin films is not known in the currently available conventional technologies. The aforementioned ALD process requires huge cost for introduction and maintenance of a manufacturing system, and yet applicable semiconductors and metals are limited. Further, it is very difficult to obtain an ultrathin atomic layer with a thickness corresponding to several atoms, even if the ALD process can be applied.

This invention has been made in order to solve these problems, and a first object of the invention is to provide a high-quality, large-area graphene substrate which is directly usable for production of semiconductor devices, and a semiconductor device produced using such a graphene substrate. A second object of the invention is to provide an atomic layer thin film substrate which is produced from the graphene substrate and is directly usable for production of semiconductor devices, and a semiconductor device produced using such an atomic layer thin film substrate.

### Means for Solving the Problems

In order to solve the aforementioned problems, a first aspect of this invention provides a substrate formed by stacking, on a semiconductor or metal layer, a graphene layer formed by chemical vapor deposition using a metal catalyst, an oxide layer for diffusing the metal catalyst, and a compound or alloyed layer formed by combination or alloying between the metal catalyst and the semiconductor or metal layer.

A second aspect of this invention provides a substrate formed by stacking, on a semiconductor or metal layer, an atomic layer thin film formed by reducing an oxide layer with a graphene layer formed by chemical vapor deposition using a metal catalyst, the oxide layer for diffusing the metal catalyst, and a compound or alloyed layer formed by combination or alloying between the metal catalyst and the semiconductor or metal layer.

A third aspect of this invention provides a substrate formed by stacking, on a semiconductor or metal layer, a graphene layer formed by chemical vapor deposition using a metal catalyst, an atomic layer thin film formed by reducing an oxide layer with the graphene layer, the oxide layer for diffusing the metal catalyst, and a compound or alloyed layer formed by combination or alloying between the metal catalyst and the semiconductor or metal layer.

A fourth aspect of this invention is a semiconductor element manufactured with the substrate described above.

A fifth aspect this invention provides a manufacturing method of a substrate including: (a) forming an oxide layer on a semiconductor or metal layer; (b) forming a metal catalyst layer required for graphitization on the oxide layer; (c) forming a graphene layer on the metal catalyst layer through thermal decomposition of a carbon source and cooling; and (d) performing heating to cause the metal catalyst layer to diffuse into the oxide layer and to cause the metal catalyst layer to be absorbed as a compound or alloyed layer by combination or alloying with the semiconductor or metal so that the graphene layer directly faces the oxide layer.

A sixth aspect of this invention provides a manufacturing method of a substrate including: (a) forming an oxide layer on a semiconductor or metal layer; (b) forming a metal catalyst layer required for graphitization on the oxide layer; (c) forming a graphene layer on the metal catalyst layer through thermal decomposition of a carbon source and cooling; (d) performing heating to cause the metal catalyst layer to diffuse into the oxide layer and to cause the metal catalyst layer to be absorbed as a compound or alloyed layer by combination or alloying with the semiconductor or metal so that the graphene layer directly faces the oxide layer; and (e) performing further heating to form an atomic layer thin film on the oxide layer by reducing an upper layer of the oxide with the graphene layer.

A seventh aspect of this invention provides a manufacturing method of a substrate including: (a) forming an oxide layer on a semiconductor or metal layer; (b) forming a metal catalyst layer required for graphitization on the oxide layer; (c) forming a graphene layer on the metal catalyst layer through thermal decomposition of a carbon source and cooling; (d) performing heating to cause the metal catalyst layer to diffuse into the oxide layer and to cause the metal catalyst layer to be absorbed as a compound or alloyed layer by combination or alloying with the semiconductor or metal so that the graphene layer directly faces the oxide layer; and (f) performing further heating to form a composite atomic layer thin film comprising a stacked structure including of an upper layer of the graphene layer and an atomic layer thin film by reducing an upper layer of the oxide layer with a lower layer of the graphene layer.

An eighth aspect of this invention provides a manufacturing method of a semiconductor element including the manufacturing method of a substrate according to any one of the fifth to seventh aspects of the invention.

### Advantageous Effects of the Invention

This invention is able to provide a high-quality, large-area graphene substrate which is directly usable for production of semiconductor devices, and a semiconductor device produced using such a graphene substrate.

This invention is also able to provide an atomic layer thin film substrate which is produced from the graphene substrate and is directly usable for production of semiconductor devices, and a semiconductor device produced using such an atomic layer thin film substrate.

### BRIEF DESCRIPTION OF THE DRAWINGS

FIG. 1A is a perspective view showing a graphene substrate 4A;

FIG. 1B is a perspective view showing an atomic layer thin film substrate 6B;

FIG. 1C is a perspective view showing a composite atomic layer thin film substrate 9C;

FIG. 2A is a perspective view showing a semiconductor element (field-effect transistor 14A) including a graphene layer;

FIG. 2B is a perspective view showing a semiconductor element (field-effect transistor 16B) including an atomic layer thin film;

FIG. 2C is a perspective view showing a semiconductor element (field-effect transistor 19C) including a composite atomic layer thin film;

FIG. 3A is a diagram showing a substrate manufacturing method according to this invention;

FIG. 3B is a diagram showing the substrate manufacturing method according to this invention;

FIG. 3C is a diagram showing the substrate manufacturing method according to this invention;

FIG. 3D is a diagram showing the substrate manufacturing method according to this invention;

FIG. 3E is a diagram showing the substrate manufacturing method according to this invention;

FIG. 3F is a diagram showing the substrate manufacturing method according to this invention;

FIG. 3G is a diagram showing the substrate manufacturing method according to this invention;

FIG. 4 is a diagram showing a relationship between temperature and time before and after CVD growth of graphene shown in a working example of this invention;

FIG. 5A is a perspective view showing a third working example of a semiconductor element according to this invention;

FIG. 5B is a perspective view showing the third working example of a semiconductor element according to this invention;

FIG. 6A is a perspective view showing a fourth working example of a semiconductor element according to this invention;

FIG. 6B is a perspective view showing the fourth working example of a semiconductor element according to this invention;

FIG. 6C is a perspective view showing the fourth working example of a semiconductor element according to this invention;

FIG. 7A is a cross-sectional view showing a fifth working example of a semiconductor element according to this invention;

FIG. 7B is a cross-sectional view showing the fifth working example of a semiconductor element according to this invention;

FIG. 7C is a cross-sectional view showing the fifth working example of a semiconductor element according to this invention;

FIG. 7D is a cross-sectional view showing the fifth working example of a semiconductor element according to this invention;

FIG. 7E is a cross-sectional view showing the fifth working example of a semiconductor element according to this invention;

FIG. 7F is a cross-sectional view showing the fifth working example of a semiconductor element according to this invention;

FIG. 8A is a cross-sectional view showing a sixth working example of a semiconductor element according to this invention;

FIG. 8B is a cross-sectional view showing the sixth working example of a semiconductor element according to this invention;

FIG. 8C is a cross-sectional view showing the sixth working example of a semiconductor element according to this invention;

FIG. 8D is a cross-sectional view showing the sixth working example of a semiconductor element according to this invention;

FIG. 8E is a cross-sectional view showing the sixth working example of a semiconductor element according to this invention;

FIG. 8F is a cross-sectional view showing the sixth working example of a semiconductor element according to this invention; and

FIG. 8G is a cross-sectional view showing the sixth working example of a semiconductor element according to this invention.

### LIST OF REFERENCE NUMERALS

1 Substrate

2 Oxide layer

4 Graphene layer

4A Graphene substrate

5 Compound/alloyed layer

6 Atomic thin film

6B Atomic thin film substrate

9 Composite atomic layer thin film

9C Composite atomic layer thin film substrate

11 Substrate

12 Oxide layer

14 Graphene layer channel

14A Field-effect transistor (including graphene layer)

15 Silicide layer

16 Silicon atomic layer thin film channel

16B Field-effect transistor (including atomic layer thin film)

17 Source electrode

18 Drain electrode

19 Composite atomic layer thin film channel

19C Field-effect transistor (including composite atomic layer thin film)

21 Substrate

22 Oxide layer

23 Metal catalyst layer

24 Graphene layer

24A Graphene substrate

26 Atomic layer thin film

26B Atomic layer thin film substrate

29 Composite atomic layer thin film

29C Composite atomic layer thin film substrate

31 Silicon substrate

32 Silicon oxide layer

33 Nickel layer

34 Graphene layer

34A Graphene substrate

35 Silicide layer

41 Silicon substrate

42 Silicon oxide layer

43 Nickel catalyst layer

44 Graphene layer

44A Graphene substrate

45 Silicide layer

46 Silicon atomic layer thin film

46B Silicon atomic layer thin film substrate

51 Silicon substrate

52 Silicon oxide layer

53 Nickel catalyst layer

54 Graphene layer

54A Graphene substrate

55 Nickel silicide layer

57 Source electrode

58 Drain electrode

60 Field-effect transistor (including graphene layer)

61 Silicon substrate

62 Silicon oxide layer

63 Nickel catalyst layer

64 Graphene layer

64A Graphene substrate

65 Nickel silicide layer

66 Silicon atomic layer thin film

67 Source electrode

68 Drain electrode

70 Field-effect transistor (including silicon atomic layer thin film)

### BEST MODE FOR CARRYING OUT THE INVENTION

Exemplary preferred embodiments of this invention will be described in detail, with reference to the accompanying drawings.

It should be understood that this invention is not limited to the following embodiments and working examples, but may be modified in various ways within the scope of the invention.

(Description of Configuration)

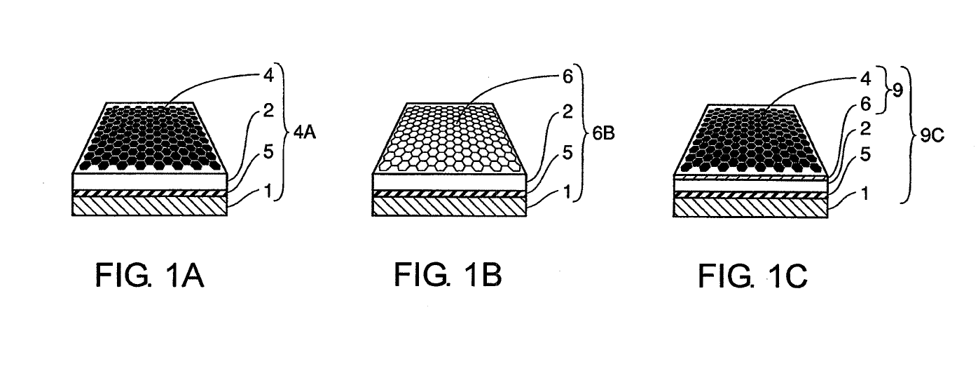

Referring to FIGS. 1A to 1C, an embodiment of this invention is illustrated. FIG. 1A is a perspective view of a graphene layer 4 and a graphene substrate 4A, FIG. 1B is a perspective view of an atomic layer thin film 6 and an atomic layer thin film substrate 6B, and FIG. 1C is a perspective view of a composite atomic layer thin film 9 and a composite atomic layer thin film substrate 9C. As shown in FIG. 1A, the graphene layer 4 is mounted on a layer (compound/alloyed layer 5) containing an oxide of a semiconductor or metal. The graphene layer 4 is formed by CVD using a metal catalyst. The number of layers in the graphene layer 4 is one to about 30. The substrate 1 is formed of a semiconductor or a metal. The metal catalyst that has been used for growth of the graphene layer 4 is absorbed as a compound/alloyed layer 5 at an interface between an oxide layer 2 and the substrate 1 by diffusing through the oxide layer 2 into an upper layer of the substrate 1 to be combined or alloyed with the same. The substrate 1 not only functions to absorb the metal catalyst by combining or alloying the same but also functions to support the graphene layer 4 on the oxide layer 2. A structure comprising the graphene layer 4, the oxide layer 2, the compound/alloyed layer 5, and the substrate 1 is the graphene substrate 4A.

The graphene layer 4 and the graphene substrate 4A according to this invention bring about an advantageous effect that the graphene layer 4 is insulated from the surroundings due to the fact that the graphene layer 4 is located on the oxide layer 2. It can be assimilated to the effect obtainable by SOI (Silicon On Insulator) substrates used in the existing semiconductor industry. This effect is attributable to a unique new method of the present invention in which the metal catalyst, which tends to short-circuit the graphene layer 4 in spite of being necessary for CVD growth of the graphene layer 4, is absorbed by the substrate 1 through the oxide layer 2. Accordingly, the graphene layer 4 and the graphene substrate 4A according to this invention can be directly used for the manufacture of semiconductor devices in the same manner as monocrystal silicon substrates used in the existing semiconductor industry. In particular, when a silicon substrate is used as the substrate 1, time-proven semiconductor technology can be applied to the manufacture of semiconductor devices comprising graphene, which eliminates the need of any particular semiconductor manufacturing technology for graphene. As a result, an additional effect of reduction of development cost and manufacturing cost can be obtained. Another benefit when a silicon substrate is used as the substrate 1 is obtained from the presence of a silicide layer. In this case, the oxide layer 2 is a silicon oxide layer, and the compound/alloyed layer 5 is a silicide layer. Specifically, a benefit is obtained that the silicide layer can be used as an electrode or wiring insulated from the graphene via the silicon oxide layer. For example, the use of the substrate of this invention makes it possible to form a capacitor comprising the graphene layer 4, a silicon oxide layer (oxide layer 2) and a silicide layer (compound/alloyed layer 5), or to form a gate stack comprising the graphene layer 4 as a semiconductor channel, a silicon oxide layer (oxide layer 2) as a gate insulation layer, and a silicide layer (compound/alloyed layer 5) as a gate electrode. Further, while the graphene layer 4 and the silicide layer (compound/alloyed layer 5) face to each other in parallel, comprising the same shape and the same size, a lithography can be used to define the graphene layer 4 and a metal catalyst layer which is to be the silicide layer (compound/alloyed layer 5) in a desired shape, size and position, and then a suitable method such as oxidation or the like can be used to remove the graphene layer 4, whereby the silicide layer (compound/alloyed layer 5) is left as it is and can be used as wiring in the substrate.

An atomic layer thin film 6 and an atomic layer thin film substrate 6B shown in FIG. 1B are obtained by oxidation-reduction of the graphene layer 4 and the graphene substrate 4A shown in FIG. 1A. From a viewpoint of compositional features, since the atomic layer thin film 6 is formed by an upper layer of the oxide layer 2 being partially reduced by the graphene, the atomic layer thin film 6 is composed of semiconductor or metallic elements comprising the oxide layer 2. From a viewpoint of the structural features, the atomic layer thin film 6 is located on the oxide layer 2, that is, on an insulator suitable for production of the element. Moreover, since the graphene, serving as a reducing agent, is ultrathin in thickness, the atomic layer thin film produced by oxidation-reduction reaction also becomes ultrathin. Specifically, the atomic layer thin film 6 generally has a thickness of 10 nm or less, and the minimum thickness is sub 1 nm. The compound/alloyed layer 5 located directly under the oxide layer 2 is produced as a result of the metal catalyst for growth of graphene being combined or being alloyed with the upper layer of the substrate 1. The atomic layer thin film substrate 6B is the substrate composed of the atomic layer thin film 6, the oxide layer 2, the compound/alloyed layer 5, and the substrate 1. The graphene as the reducing agent functions as a sacrificial layer for forming the atomic layer thin film, and generally totally disappears as carbon monoxide or carbon dioxide as a result of the oxidation reaction. However, as shown in FIG. 1C, only a lower part of the graphene layer 4 can be intentionally used as a reducing agent while leaving an upper part of the graphene layer 4, so that a composite atomic layer thin film 9 comprising a two-layer structure including the graphene layer 4 and the atomic layer thin film 6 derived from the oxide layer can be obtained. The composite atomic layer thin film substrate 9C is provided by this substrate composed of the graphene layer 4, the atomic layer thin film 6, the oxide layer 2, the compound/alloyed layer 5, and the substrate 1.

The atomic layer thin film 6 and the atomic layer thin film substrate 6B have the same effects as those of the graphene layer 4 and the graphene substrate 4A when the structural element of the atomic layer thin film 6 is a semiconductor element. These effects are the same effects as those of the aforementioned SOI substrate. Especially when the substrate 1 is a silicon substrate, it serves as an ultimate SOI substrate. This is because a silicon layer on silicon oxide is an ultrathin silicon layer with an ultimately small thickness. Accordingly, the atomic layer thin film 6 and the atomic layer thin film substrate 6B are expected to be utilized in a semiconductor device produced from an SOI substrate. Furthermore, when the structural element of the atomic layer thin film 6 is a metallic element, the atomic layer thin film 6 can be used as wiring/electrode. Since this wiring/electrode is derived from a very thin graphene layer 4, an advantageous effect can be achieved that the film thickness is ultrathin.

The composite atomic layer thin film 9 and the composite atomic layer thin film substrate 9C provide two advantageous effects. The first one is an effect that the thickness of the graphene layer 4 and the number of layers of the graphene layer 4 are made controllable. The composite atomic layer thin film 9 is formed, as described above, by using a part of the graphene layer 4 as a reducing agent to transform the oxide layer 2 into a semiconductor or metallic atomic layer thin film 6. Accordingly, in a different viewpoint, the thickness of the graphene layer 4 is decreased by the oxidation reaction with the oxide layer 2. The other effect is obtained when the composite atomic layer thin film 9 is of a two-layer structure including the graphene layer 4 and a silicon atomic layer thin film (atomic layer thin film 6). When this composite atomic layer thin film 9 is used as a channel of a semiconductor element, the silicon atomic layer thin film (atomic layer thin film 6) serves as an impurity-doped layer as a carrier supply source, and the graphene layer 4 serves as a carrier traveling layer. It can be liken to a channel of a HEMT (High Electron Mobility Transistor) in which a semiconductor region doped with a donor impurity supplying electrons and an active region where electrons travel are made of different compound semiconductors. In the case of an HEMT, since there is no impurity ions in the electron traveling layer, electrons are not scattered by impurity ions. Therefore, the mobility is increased by that much and more rapid operation is possible. The composite atomic layer thin film 9 according to this invention also provides the same effect, and it can be expected that the high mobility that graphene inherently has is increased to its theoretical limitation. Further, this invention is superior to the HEMT in that whereas the carrier is limited to electrons in the HEMT, either electrons and electron holes can be used as the carrier to ensure high mobility according to this invention. This is because the silicon atomic layer thin film (atomic layer thin film 6) can be doped with either a donor impurity or an acceptor impurity. No suitable doping method has been known for graphene. Accordingly, from a different viewpoint, this invention is able to provide an effective pn conduction control method while increasing the high mobility inherent to the graphene to its utmost limit. This synergistic effect deserves special mention.

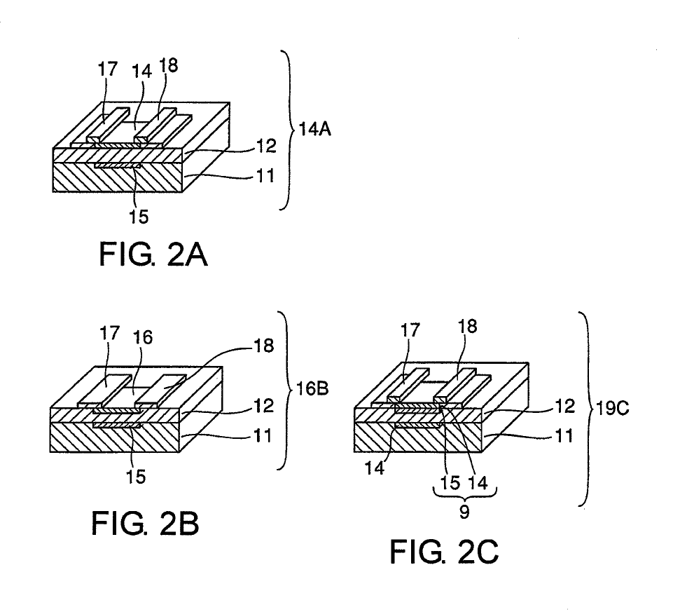

Referring to FIG. 2A, a perspective view including a cross-sectional (front) view of a semiconductor element comprising a graphene layer according to an embodiment of this invention is shown. A field-effect transistor 14A is shown as an example of the semiconductor element.

In FIG. 2A, the reference numeral 11 indicates a silicon substrate, and 12 indicates a silicon oxide layer. The silicon oxide layer 12 serves as a gate insulation layer for a gate electrode 15. The gate electrode 15 has silicide produced by the metal catalyst layer for growth of graphene being absorbed by the interface between the silicon substrate 11 and the silicon oxide layer 12. The gate electrode 15 functions to control carrier conduction in a graphene layer channel 14 located directly above the gate electrode 15. The graphene layer channel 14 is formed by CVD using a metal catalyst, and functions to transport carriers between the source electrode 17 and the drain electrode 18. Since the gate electrode 15 is originally derived from the metal catalyst for growth of graphene, the gate electrode 15 has the same size and shape as those of the graphene layer channel, and is located at the same two-dimensional position in a horizontal plane as the graphene layer channel. This means that this invention provides an advantageous effect that the gate electrode 15 can be formed in a self-aligned manner with respect to the graphene layer channel 14. The layer of the metal catalyst for growth of graphene can be formed to have an arbitrary size and shape at an arbitrary position by using a lithography technique, and hence the graphene layer channel 14 and the gate electrode 15 can be defined to an arbitrary size, shape, and position. In this manner, a field-effect transistor 14A comprising a graphene layer as a channel is produced. Since graphene possesses the highest mobility of all the materials, the field-effect transistor 14A enjoys an ultrafast speed and ultralow power consumption. Further, since the field-effect transistor 14A is formed on the silicon substrate, it exhibits high affinity with a semiconductor technology using silicon as a base. This provides a benefit that the field-effect transistor 14A can be mounted together with silicon semiconductor elements, and a synergistic effect can be expected between a graphene semiconductor element and a silicon semiconductor element. It is also possible to produce a field-effect transistor comprising a double-gate structure by forming a second gate electrode on the graphene layer channel 14 between the source electrode 17 and the drain electrode 18 through an insulator layer. When the double-gate structure is employed, a benefit can be obtained that one of the gates is used for normal control of channel conduction, and the other is used for threshold control. Further, when the channel is formed of two graphene layers, the double-gate structure makes it possible to increase the band gap by applying an electric field to generate asymmetry between the upper and lower graphene layers. In this case, a benefit can be obtained that the on/off ratio is dramatically improved thanks to the band gap opening.

Referring to FIG. 2B, a perspective view including a (front) cross-sectional view is shown to illustrate a semiconductor element comprising an atomic layer thin film according to an embodiment of this invention.

Here, a field-effect transistor 16B is shown as an example of the semiconductor element.

There are provided, as components, a silicon substrate 11, a silicon oxide layer 12, a gate electrode 15 comprising a silicide, a silicon atomic layer thin film channel 16, a source electrode 17, and a drain electrode 18. As a whole, a field-effect transistor 16B comprising a silicon atomic layer thin film as a channel is provided. The functions of the components are the same as described above. The silicon atomic layer thin film channel 16 is formed by reducing a part of an upper layer of the silicon oxide layer by a method using the graphene layer as a sacrificial layer. This provides an advantageous effect that the silicide gate electrode 15 derived from a metal catalyst for formation of the graphene layer assumes a self-aligned position. Further, since the silicon atomic layer thin film channel 16 is characterized by being so thin that it is difficult to form using a normal method, the field-effect transistor 16B enjoys benefits of rapid operation and low power consumption. It is also possible to form a field-effect transistor comprising a double-gate structure by forming a second gate electrode on the silicon atomic layer thin film channel 16 between the source electrode 17 and the drain electrode 18. The double-gate structure provides an advantageous effect that one of the gates can be used for normal control of channel conduction, and the other can be used for threshold control.

Referring to FIG. 2C, a perspective view including a (front) cross-sectional view is shown to illustrate a semiconductor element including a composite atomic layer thin film according to an embodiment of this invention.

Here, a field-effect transistor 19C is shown as an example of the semiconductor element.

There are provided, as components, a silicon substrate 11, a silicon oxide layer 12, a gate electrode 15 comprising a silicide, a composite atomic layer thin film channel 19 including a graphene layer channel 14 as an upper layer and a silicon atomic layer thin film channel 16 as a lower layer, a source electrode 17, and a drain electrode 18. As a whole, a field-effect transistor 19C comprising a composite atomic layer thin film as a channel is formed. The functions of the components are the same as described above. The composite atomic layer thin film channel 19 is formed by reducing a part of an upper layer of the silicon oxide layer by a method using a part of the graphene layer as a sacrificial layer. The silicon atomic layer thin film channel 16 serves as a charge supply layer, and the graphene layer channel 14 serves as a carrier transfer layer, whereby a benefit is obtained that the field-effect transistor 19C is enabled operate at a ultrahigh speed realized by maximizing the high mobility that graphene inherently has. Obviously, a benefit can also be obtained that the power consumption is reduced to its ultimate limit. It is also possible to form a field-effect transistor comprising a double-gate structure by forming a second gate electrode on the graphene layer channel 14 between the source electrode 17 and the drain electrode 18 through an insulator layer. When the double-gate structure is employed, an advantageous effect can be obtained that one of the gates is used for normal control of channel conduction and the other is used for threshold control.

(Description of Manufacturing Method)

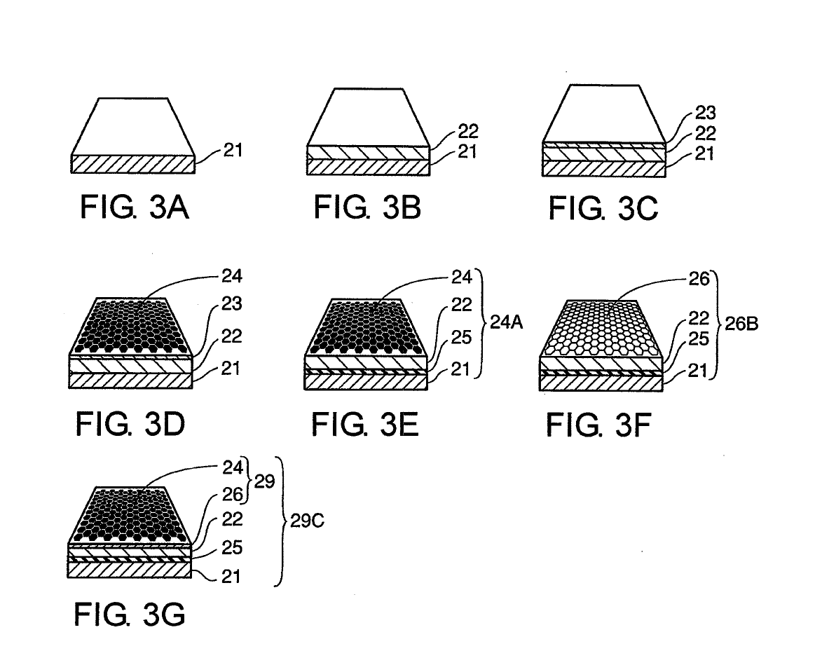

Referring to FIGS. 3A to 3G, a manufacturing method according to an embodiment of the invention will be described. FIGS. 3A to 3E illustrate a fabrication method of a graphene layer 24 and a graphene substrate 24A, and FIGS. 3A to 3F illustrate a fabrication method of an atomic layer thin film 26 and an atomic layer thin film substrate 26A, and FIGS. 3A to 3E and FIG. 3G illustrate a fabrication method of a composite atomic layer thin film 29 and a composite atomic layer thin film substrate 29C.

FIGS. 3A to 3E illustrate a fabrication method of the graphene layer 24 and the graphene substrate 24A. First, an appropriate substrate 21 is prepared as shown in FIG. 3A. The substrate material is a semiconductor or a metal, and is at least one selected from the group consisting of boron (B), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), germanium (Ge), zirconium (Zr), niobium (Nb), molybdenum (Mo), ruthenium (Ru), palladium (Pd), silver (Ag), hafnium (Hf), tantalum (Ta), tungsten (W), rhenium (Re), osmium (Os), iridium (Ir), bismuth (Bi), gallium arsenide (GaAs), indium phophide (InP), indium antimonide (InSb), GaN (gallium nitride), AlN (aluminum nitride), and silicon carbide (SiC). Subsequently, as shown in FIG. 3B, a layer containing an oxide of a semiconductor or metal (oxide layer 22) is formed on the substrate 21. The formation of the oxide layer 22 may be performed not only by a film formation method such as sputtering, deposition and coating, but also by a method of thermally oxidizing the substrate itself. The material for the oxide layer may be any one or a combination selected from the group consisting of lithium oxide (I)/Li₂O, beryllium oxide (II)/BeO, boron oxide (II)/B₂O₃, sodium oxide (I)/Na₂O, magnesium oxide (II)/MgO, aluminum oxide (III)/Al₂O₃, silicon oxide (IV)/SiO₂, phosphorus oxide (V)/P₄O₁₀, phosphorus oxide (IV)/PO₂, potassium oxide (I)/K₂O, calcium oxide (II)/CaO, scandium oxide (III)/Sc₂O₃, titanium oxide (IV)TiO₂, titanium oxide (III, IV)Ti₃O₅, titanium oxide (III)/Ti₂O₃, titanium oxide (II)/TiO, vanadium oxide (V)N₂O₅, vanadium oxide (IV)/VO₂, vanadium oxide (III)/V₂O₃, vanadium oxide (II)NO, chromium oxide (II)/CrO, chromium oxide (II,III)Cr₃O₄, chromium oxide (III)/Cr₂O₃, manganese oxide (IV)/MnO₂, manganese oxide (III)/Mn₂O₃, manganese oxide (II,III)/Mn₃O₄, manganese oxide (II)/MnO, iron oxide (III)/Fe₂O₃, iron oxide (II)/FeO, iron oxide(II,III)/Fe₃O₄, cobalt oxide (II,III)/Co₃O₄, cobalt oxide (II)CoO, nickel oxide (II)/NiO, copper oxide(II)/CuO, copper oxide(I)/Cu₂O, zinc oxide (II)/ZnO, gallium oxide(III)/Ga₂O₃, germanium oxide (IV)/GeO₂, arsenic oxide (III)/As₂O₃, selenium oxide (IV)/SeO₂, rubidium oxide (IV)/RuO₂, strontium oxide (II)/SrO, yttrium oxide (III)/Y₂O₃, zirconium oxide (IV)/ZrO₂, niobium oxide (V)/Nb₂O₅, niobium oxide (IV)/NbO₂, niobium oxide (II)/NbO, molybdenum oxide (VI)/MoO₃, molybdenum oxide (IV)/MoO₂, ruthenium oxide (VI)/RuO₃, ruthenium oxide (VIII)/RuO₄, ruthenium oxide (IV)/RuO₂, rhodium oxide(III)/Rh₂O₃, palladium oxide (II)/PdO, silver oxide (I)/Ag₂O, cadmium oxide (II)/CdO, indium oxide (III)/In₂O₃, tin oxide (IV)/SnO₂, antimony oxide(III)/Sb₂O₃, tellurium oxide (IV)/TeO₂, barium oxide (II)/BaO, cerium oxide (IV)/CeO₂, cerium oxide (III)/Ce₂O₃, praseodymium oxide (III)/Pr₂O₃, neodymium oxide (III)/Nd₂O₃, samarium oxide (III)/Sm₂O₃, europium oxide (III)/Eu₂O₃, gadolinium oxide (III)/Gd₂O₃, terbium oxide (III)/Tb₂O₃, dysprosium oxide (III)/Dy₂O₃, hafnium oxide (IV)/HfO₂, tantalum oxide (V)/Ta₂O₅, tungsten oxide (VI)/WO₃, tungsten oxide (IV)/WO₂, rhenium oxide (IV)/ReO₂, osmium oxide (IV)/OsO₂, iridium oxide (IV)/IrO₂, mercury oxide (I)/Hg₂O, lead oxide (IV)/PbO₂, lead oxide (II,III)/Pb₃O₄, lead oxide (II)/PbO, bismuth oxide (III)/Bi₂O₃, thorium oxide (IV)/ThO₂, and uranium oxide (IV)/UO₂. Subsequently, as shown in FIG. 3C, a layer comprising a metal catalyst required for growth of graphene (metal catalyst layer 23) is formed. The formation of the metal catalyst layer 23 may be performed by a film formation method such as sputtering or deposition. The metal catalyst contains at least a metal element, and desirably contains any one of chromium (Cr), manganese (Mn), iron (Fe), cobalt (Co), nickel (Ni), copper (Cu), molybdenum (Mo), ruthenium (Ru), rhodium (Rh), palladium (Pd), silver (Ag), tungsten (W), rhenium (Re), osmium (Os), iridium (Ir), platinum (Pt), and gold (Au). After that, as shown in FIG. 3D, CVD growth is performed on the metal catalyst layer 23 using a carbon source as a material to form the graphene layer 24. The CVD growth is performed within a temperature range of 500 to 1200° C. The temperature range should be set, according types of the metal catalyst and the oxide, such that the catalyst metal is not dissipated in the oxide layer 22. The carbon source usable for this purpose is a saturated hydrocarbon such as methane gas, ethane, propane, and butane, an unsaturated hydrocarbon such as ethylene, acetylene, and benzene, or an alcohol such as methyl alcohol and ethyl alcohol, or carbon monoxide. After the growth of graphene, as shown in FIG. 3E, the metal catalyst layer 23 is diffused into the oxide layer 22 to be combined or alloyed with a material forming the substrate 21 at the interface between the oxide layer 22 and the substrate 21, so that a compound or alloyed layer 25 is formed. The diffusion, combination and alloying of the metal catalyst layer 23 are performed by heating. The temperature for heating, that is the temperature for diffusion, combination and alloying is set in a range of 500 to 1500° C. However, the temperature should be set in such a range that no oxidation-reduction reaction occurs between the graphene layer 24 and the oxide layer 22. In this manner, the graphene layer 24 and the graphene substrate 24A are completed.

FIGS. 3A to 3F illustrate a fabrication method of the atomic layer thin film 26 and an atomic layer thin film substrate 26B. The fabrication method shown in FIGS. 3A to 3E is the same as the fabrication method of the graphene layer 24 and the graphene substrate 24A. As shown in FIG. 3F, a part of an upper layer of the oxide layer is reduced by heating to cause the entire graphene layer 24 to serve as a reducing agent, whereby the atomic layer thin film 26 is formed. As a result, the atomic layer thin film substrate 26B is obtained, comprising the atomic layer thin film 26, the oxide layer 22, and the compound or alloyed layer 25, and the substrate 21. During this process, the graphene layer 24 serving as a sacrificial layer is oxidized and completely disappears in the gas phase as carbon monoxide or carbon dioxide, while only the atomic layer thin film 26 is left, comprising a semiconductor or metallic element which forms the oxide layer 22 by carbon reduction. The heating temperature during this process is set to be equal to or higher than a temperature level at which oxidation-reduction reaction occurs. Specifically, the heating temperature is set to a range from 500 to 3500° C. In case the substrate or the like is not resistant enough to high temperature, only the area requiring oxidation-reduction may be heated locally and briefly by using laser annealing or the like.

FIGS. 3A to 3E and FIG. 3G illustrate a fabrication method of the composite atomic layer thin film 29 and the composite atomic layer thin film substrate 29C. The fabrication method shown in FIGS. 3A to 3E is in common with those of the graphene layer 24 and the graphene substrate 24A. As shown in FIG. 3G, a part of an upper layer of the oxide layer 22 is reduced by heating to use a part of a lower layer of the graphene layer 24 as a reducing agent, whereby the composite atomic layer thin film substrate 29C is obtained, comprising the composite atomic layer thin film 29 including the graphene layer 24 as the upper layer and the atomic layer thin film 26 as the lower layer, the composite atomic layer thin film 29, the oxide layer 22, the compound or alloyed layer 25, and the substrate 21. During this process, the lower layer of the graphene layer 24 serving as a sacrificial layer is oxidized and completely disappears in the gas phase as carbon monoxide or carbon dioxide, while the upper layer of the graphene layer 24 is left. The atomic layer thin film 26 comprising a semiconductor or metallic element which forms the oxide layer 22 by carbon reduction is left, comprising the interface in common with the graphene layer 24. The heating temperature during this process is set to be equal to or higher than a temperature level at which oxidation-reduction reaction occurs. In order to precisely control the heating temperature and heating time, laser annealing is suitable.

### Working Example 1

### CVD Growth of Graphene Layer and Dependency on Metal Catalyst

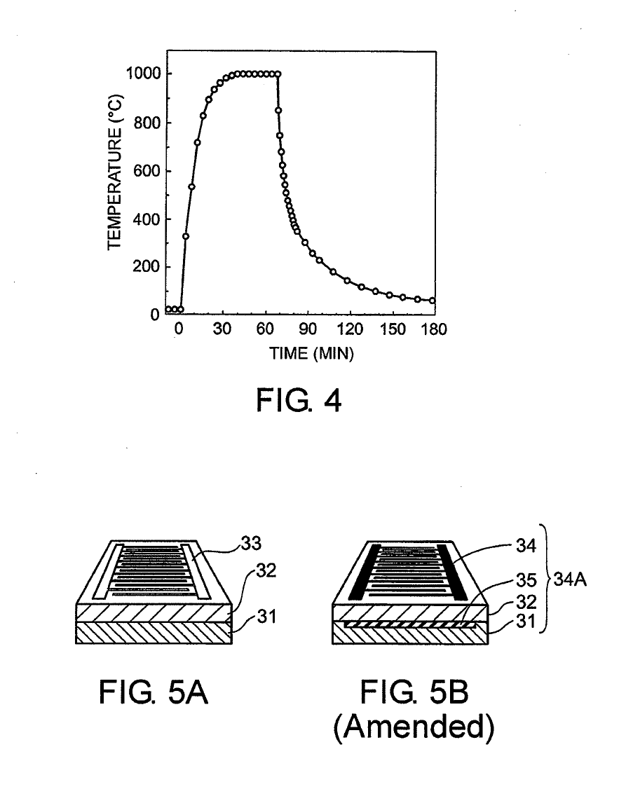

The graphene layer 24 and the graphene substrate 24A were fabricated according to the fabrication method shown in FIGS. 3A to 3E. A silicon substrate as the substrate 21 was thermally oxidized to form a silicon oxide layer (oxide layer 22), and then iron, nickel and copper as metal catalysts were sputtered to form a film, respectively. Using each of these metal catalysts, CVD growth of graphene was performed at a temperature of 1000° C., using methane as a carbon source. FIG. 4 represents a typical thermal profile before and after the CVD growth of graphene. The CVD growth was performed in the procedures as described below. The substrate comprising the metal catalyst film formed thereon was heated from room temperature to a CVD growth temperature under the flow of gas mixture of hydrogen and argon, and the CVD growth temperature was kept for about 10 to 60 minutes to age the metal catalysts. After that, flow of gas mixture of hydrogen and methane was supplied for from 30 seconds to 30 minutes to let the graphene layer 24 grow. Finally, the substrate was cooled to room temperature under the flow of gas mixture of hydrogen and argon. A surface of the grown graphene was observed with an atomic force microscope or a scanning electron microscope. The result revealed that a satisfactory graphene layer 24 could be formed no matter which of iron, nickel and copper was used as the metal catalyst. The number of layers of the graphene layer 24, which could be controlled depending on the type of catalyst, the CVD growth temperature, and the CVD growth, was one to about 30 layers.

### Working Example 2

### CVD Growth of Graphene Layer and Dependency on CVD Growth Conditions

Effects of CVD growth conditions on growth of graphene when the metal catalyst was nickel were examined. Examined growth parameters were temperature drop rate [° C./min] after CVD growth, and methane concentration [% by volume] in gas mixture of argon, hydrogen and methane. The other CVD growth conditions including metal catalyst aging conditions and graphene growth temperature (1000° C.) were kept constant. Surface of grown graphene was evaluated with the use of an atomic force microscope, a scanning electron microscope or the like. Table 1 shows a relationship between temperature drop rate and methane concentration given to the growth of graphene, and summarizes features of graphene obtained under each condition. What is noticeable in the first place is that when the methane concentration was 0.25% by volume, little growth of graphene was observed no matter how much is the temperature drop rate, whereas when the methane concentration was 1.00% by volume or more, multilayer graphene (including of more than two layers) constituted a large part regardless of temperature drop rate. Growth of one- or two-layer graphene was observed when the methane concentration was 0.50 to 0.75% by volume, and the temperature drop rate was 25° C./min. Having an overview of the result, the multilayer graphene is obtained more likely when the methane concentration is high, whereas one- or two-layer graphene is obtained more likely when the temperature drop rate is low. More particularly, in order to obtain multilayer graphene, the methane concentration must be set to 1.00% by volume or more, or the methane concentration must be set to 0.50 to 0.75% by volume while the temperature drop rate is set to 50° C./min or higher. In order to obtain one- or two-layer graphene, the methane gas concentration must be set to 0.50 to 0.75% by volume while the temperature drop rate is kept at 25° C./min or lower.

TABLE 1

| Temperature | | | | |
|---|---|---|---|---|
| drop rate | Methane concentration in gas mixture [% by volume] | | | |
| [° C./min] | 0.25 | 0.5 | 0.75 | 1 |
| 100 | No graphene | No graphene | Multilayer | Multilayer |
| 50 | growth | growth | graphene | graphene |
| 25 | | One- or | One- or | |
| 5 | | two-layer | two-layer | |
| | | graphene | graphene | |

### Working Example 3

### Fabrication of Graphene Layer and Graphene Substrate

A graphene layer was formed on a comb-like electrode structure 33 as shown in FIG. 5A in the same manner as in the fabrication method shown in FIGS. 3A to 3E to fabricate a graphene substrate.

FIG. 5A shows a comb-like electrode structure in which a nickel catalyst layer 33 has been vapor deposited on a silicon oxide layer 32/silicon substrate 31 by being defined by lithography. CVD growth of graphene was performed on this comb-like nickel catalyst layer 33 under the conditions indicated in working example 2. Observation with scanning electron microscope or the like revealed that graphene layers 34 including one- or two-layer graphene and of multilayer graphene were formed on the comb-like electrode structure (nickel catalyst layer 33) depending on the CVD conditions such as methane concentration and temperature drop rate. Consequently, the graphene layer 34/nickel catalyst layer 33/silicon oxide layer 32/silicon substrate 31 was heated at 1200° C. for 6 hours under vacuum or inert atmosphere, resulting in a structure shown in FIG. 5B. The observation with a scanning electron microscope revealed that the graphene layer 34 was located not on the nickel catalyst layer 33 but on the silicon oxide layer 32. Further, as a result of analysis by SIMS (Secondary Ionization Mass Spectrometry), it was confirmed that a silicide layer 35 was located at the interface between the silicon oxide layer 32 and the silicon substrate 31. This means that the nickel catalyst layer was diffused into the silicon oxide layer and reacted with silicon at the interface. Accordingly, the layered structure of the substrate includes the graphene layer 34, the silicon oxide layer 32, the silicide layer 35, and the silicon substrate 31, and it was proved that a graphene substrate 34A comprising the same structure as that of the graphene layer 4 and the graphene substrate 4A shown in FIG. 1A was fabricated.

### Working Example 4

### Fabrication of Atomic Thin Film and Atomic Thin Film Substrate

An atomic layer thin film was formed on a comb-like electrode structure as shown in FIG. 5A to fabricate an atomic layer thin film substrate in the same manner as the fabrication method shown in FIGS. 3A to 3F.

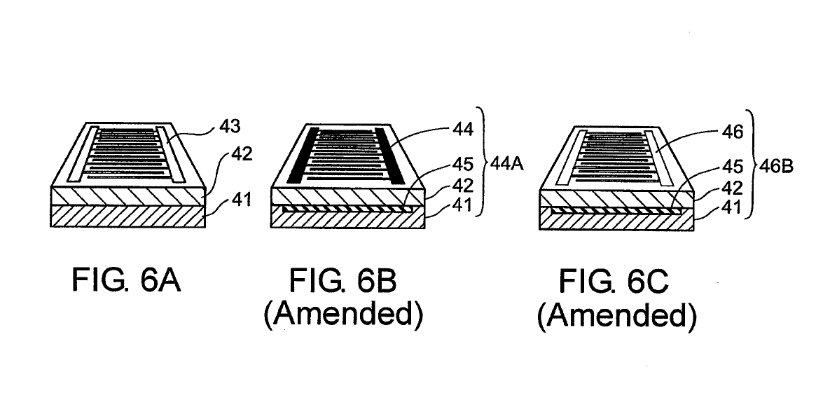

FIG. 6A shows a comb-like electrode structure which has been produced by a method in which a silicon oxide layer 42 is formed on a silicon substrate 41 by thermal oxidation and then a nickel catalyst layer 43 is formed thereon by being defined by lithography. FIG. 6B shows a result obtained after growth of graphene and interface silicidation were performed in the same manner as in the working example 3. This structure was analyzed in the same manner as in the working example 3, whereby it was revealed that the structure was a graphene substrate 44A comprising a stacked structure including a graphene layer 44, the silicon oxide layer 42, a silicide layer 45, and the silicon substrate 41. Subsequently, this graphene substrate 44A was heated at 1700° C. for 6 hours under vacuum or inert atmosphere. FIG. 6C shows a result thus obtained. It should be noted that this heating temperature exceeds a temperature of 1668° C. at which silicon oxide is reduced by carbon. As a result of surface observation with an atomic force microscope or scanning electron microscope and analysis by EDX (Energy Dispersive X-ray Spectrometry), it was confirmed that the comb-like electrode on the surface of the structure shown in FIG. 6C was an ultrathin silicon atomic layer thin film. The thickness of the silicon atomic layer thin film 46 was dependent on the thickness of the graphene layer, and the minimum was sub 1 nm and the maximum was about 10 nm. Therefore, the stacked structure of the substrate thus fabricated was composed of the silicon atomic layer thin film 46, the silicon oxide layer 42, the silicide layer 45, and the silicon substrate 41, and hence it was proved that an atomic layer thin film and an atomic layer thin film substrate were fabricated. It was also confirmed that when the graphene substrate was heated by using laser heating in place of the aforementioned heating method while strictly controlling the heating time, only an upper part of the graphene layer could be left and a silicon atomic layer thin film could be formed directly under the left part of the graphene layer. The stacked structure of the substrate produced in this manner was composed of a graphene layer, a silicon atomic layer thin film, a silicon oxide layer, a silicide layer, and a silicon substrate, and it was proved that a composite atomic layer thin film and a composite atomic layer thin film substrate were fabricated.

### Working Example 5

### Fabrication of Field-Effect Transistor Having Graphene Layer as Channel

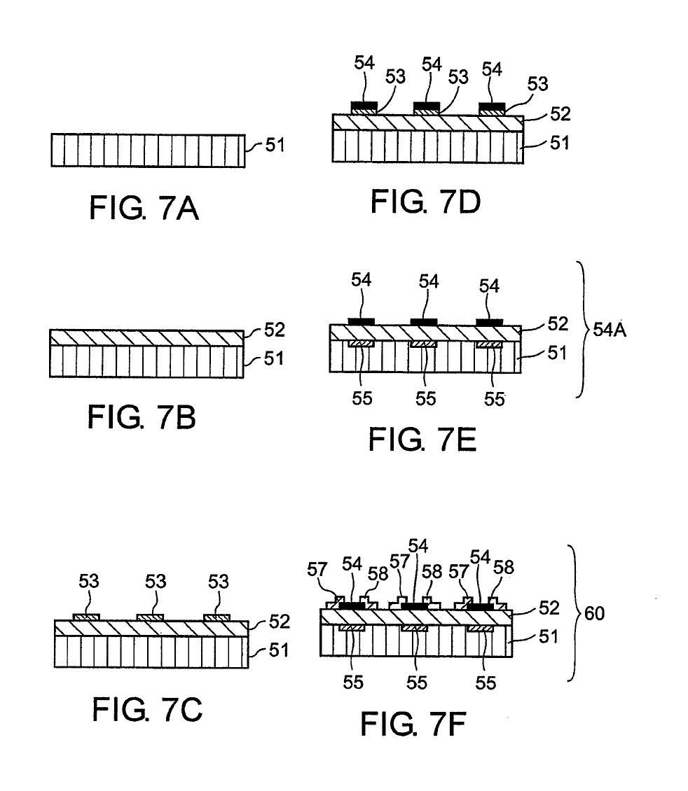

A field-effect transistor comprising a graphene layer as a channel was fabricated by a method according to this invention. A silicon substrate 51 was prepared as shown in FIG. 7A. As shown in FIG. 7B, a silicon oxide layer 52 was formed on the silicon substrate 51 by CVD with silane gas and oxygen. As shown in FIG. 7C, a nickel catalyst layer 53 for growth of graphene was laid out on the silicon oxide layer 52 by being defined with lithography. The substrate of FIG. 7C was introduced into a CVD apparatus, in which CVD growth of a graphene layer 54 (of one or two layers) was performed on the nickel catalyst layer 53 in gas mixture of argon, hydrogen and methane (methane concentration of 0.5% by volume), at a temperature of 1000° C., for duration of 5 minutes, and at a temperature drop rate of 0.5° C./min as shown in FIG. 7D. The graphene layer 54 eventually serves as a channel. Subsequently, as shown in FIG. 7E, the substrate of FIG. 7D was vacuum-heated at 1200° C. for 6 hours, whereby the nickel catalyst layer 53 was diffused into the silicon oxide layer 52 to be reacted with silicon in an upper layer of the silicon substrate so that it was absorbed as a nickel silicide layer 55 at the interface between the silicon oxide layer 52 and the silicon substrate 51. The nickel silicide layer 55 was formed in a self-aligned manner and functions as a gate electrode. Finally, a graphene substrate 54A as shown in FIG. 7F was defined by lithography so that gold was vapor deposited on each of the graphene layer 54 to form a source electrode 57 and a drain electrode 58. In this manner, a field-effect transistor 60 including a graphene layer was obtained. The gate electrode, the source electrode, and the drain electrode of this field-effect transistor 60 were interconnected and electrical measurement was conducted. As a result, favorable transistor operation was confirmed.

### Working Example 6

### Fabrication of Field-Effect Transistor Having Silicon Atomic Thin Film as Channel

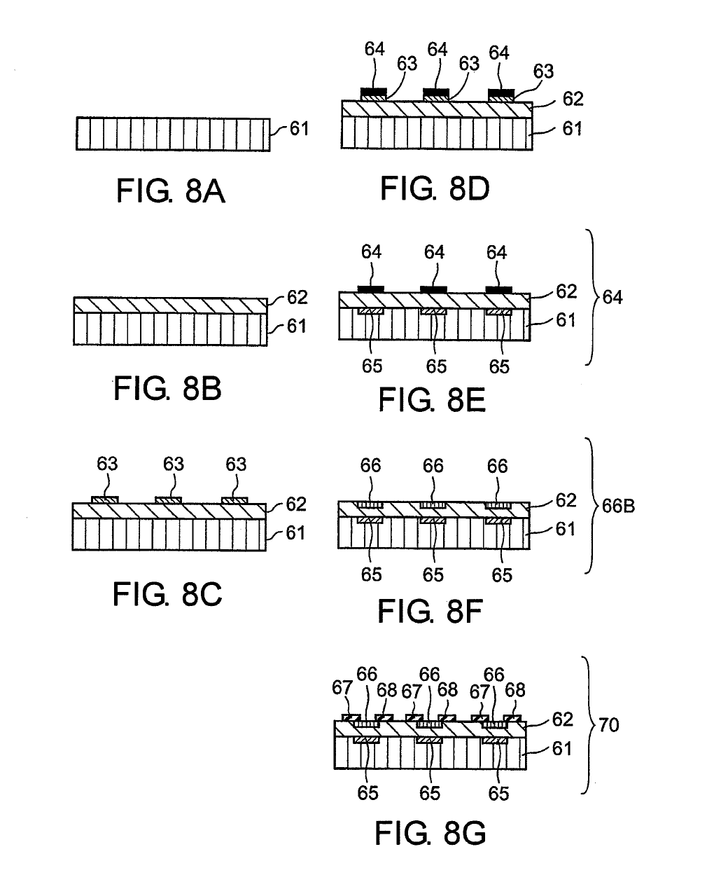

A field-effect transistor comprising a silicon atomic layer thin film as a channel was fabricated by a method according to this invention. Firstly, a silicon substrate 61 as shown in FIG. 8A was prepared. Then, a silicon oxide layer 62 was formed on the silicon substrate 61 by CVD with mixture gas of silane gas and oxygen as shown in FIG. 8B. A nickel catalyst layer 63 for growth of graphene was laid out on the silicon oxide layer by being defined with lithography as shown in FIG. 8C. Subsequently, the substrate of FIG. 8C was introduced into a CVD apparatus, in which CVD growth of a graphene layer 64 (of one or two layers) was performed in gas mixture of argon, hydrogen and methane (methane concentration of 0.5% by volume), at a temperature of 1000° C., for duration of 5 minutes, and at a temperature drop rate of 0.5° C./min as shown in FIG. 8D. As described later, the graphene layer 64 is a sacrificial layer serving as a reducing agent for silicon oxide. After the growth of the graphene layer 64, as shown in FIG. 8E, the substrate of FIG. 8D was vacuum-heated at 1200° C. for 6 hours, whereby the nickel catalyst layer 63 was diffused into the silicon oxide layer 62 to react with silicon in an upper layer of the silicon substrate, whereby it was absorbed as a nickel silicide layer 65 at the interface between the silicon oxide layer 62 and the silicon substrate 61. The nickel silicide layer 65 was formed in a self-aligned manner and functions as a gate electrode. Subsequently, as shown in FIG. 8F, a graphene substrate 64A was vacuum-heated at 1700° C. for 6 hours, so that a silicon atomic layer thin film 66 was formed by oxidation-reduction reaction between the graphene layer 64 and an upper layer of the silicon oxide layer 62. The silicon atomic layer thin film 66 serves as a channel. Finally, a silicon atomic layer thin film substrate 66B as shown in FIG. 8G was defined by lithography so that gold was vapor deposited on each of the silicon atomic layer thin film 66 to form a source electrode 67 and a drain electrode 68. In this manner, a field-effect transistor 70 including a silicon atomic layer thin film was obtained. The gate electrode, the source electrode, and the drain electrode on the field-effect transistor 70 were interconnected by a known method, and electrical measurement was conducted. As a result, favorable transistor, operation was confirmed. Further, it was confirmed in the manufacturing method shown in FIGS. 8A to 8G that when the CVD growth conditions during the growth of graphene of FIG. 8D were changed so as to produce a multilayer graphene, and the heating method used in oxidation-reduction of FIG. 8F was changed to laser heating so as to shorten the duration of oxidation-reduction, a composite atomic layer thin film comprising a graphene layer and a silicon atomic layer thin film could be obtained. As a result, a field-effect transistor including a composite atomic layer thin film also could be produced, and it was confirmed that this field-effect transistor had favorable transistor performance.

As described above, this invention provides advantageous effects as described below.

(First Effect)

It is possible to provide a high-quality and large-area graphene substrate in which there is no structural defect or wrinkles in graphene, and there is no deposition of impurities which may inhibit carrier transportation, and also to provide a manufacturing method of such a graphene substrate.

(Second Effect)

It is made possible, by causing graphene to exhibit its inherent, excellent electronic properties sufficiently, to provide a semiconductor device which is made from the aforementioned graphene substrate, capable of increasing operation speed, reducing power consumption, and increasing degree of integration, and thus has improved reliability and productivity. It is also possible to provide a manufacturing method of such a semiconductor device.

(Third Effect)

It is possible to provide a high-quality, ultrathin and large-area atomic layer thin film substrate with high versatility and low production cost, which is composed of a wide variety of semiconductor or metallic elements, and also possible to provide a manufacturing method of such an atomic layer thin film substrate.

(Fourth Effect)

It is possible to provide a semiconductor device which is made from the aforementioned atomic layer thin film, and is capable of increasing operation speed, reducing power consumption, and increasing degree of integration, and thus has improved reliability and productivity. It is also made possible to provide a manufacturing method of such a semiconductor device.

### INDUSTRIAL APPLICABILITY

This invention is applicable, for example, to semiconductor devices in electronics field characterized by low power consumption and ultrahigh operation speed such as field-effect transistors, logic circuits, memory element circuits, and AD converts, as well as semiconductor devices in optoelectronics field operable in terahertz electromagnetic waveband such as amplifiers transmitters, light sources, lasers, and ultrahigh-speed broadband information communication equipment.

This application is based upon and claims the benefit of priority from Japanese Patent Application No. 2009-190948, filed Aug. 20, 2009, the disclosure of which is incorporated herein in its entirety by reference.

1. A substrate formed by stacking, on a semiconductor or metal layer, a graphene layer formed by chemical vapor deposition using a metal catalyst, an oxide layer for diffusing the metal catalyst, and a compound or alloyed layer formed by combination or alloying between the metal catalyst and the semiconductor or metal layer, wherein the substrate, the compound or alloyed layer, the oxide layer, and the graphene layer is stacked in this order.

2. A substrate formed by stacking, on a semiconductor or metal layer, an atomic layer thin film formed by reducing an oxide layer with a graphene layer formed by chemical vapor deposition using a metal catalyst, the oxide layer for diffusing the metal catalyst, and a compound or alloyed layer formed by combination or alloying between the metal catalyst and the semiconductor or metal layer, wherein the substrate, the compound or alloyed layer, the oxide layer, and the atomic layer thin film is stacked in this order.

3. A substrate formed by stacking, on a semiconductor or metal layer, a graphene layer formed by chemical vapor deposition using a metal catalyst, an atomic layer thin film formed by reducing an oxide layer with the graphene layer, the oxide layer for diffusing the metal catalyst, and a compound or alloyed layer formed by combination or alloying between the metal catalyst and the semiconductor or metal layer, wherein the substrate, the compound or alloyed layer, the oxide layer, the atomic layer thin film, and the graphene layer is stacked in this order.

4. The substrate as claimed in claim 1, wherein the metal catalyst is at least one selected from the group consisting of chromium (Cr), manganese (Mn), iron (Fe), cobalt (Co), nickel (Ni), copper (Cu), molybdenum (Mo), ruthenium (Ru), rhodium (Rh), palladium (Pd), silver (Ag), tungsten (W), rhenium (Re), osmium (Os), iridium (Ir), platinum (Pt), and gold (Au).

5. The substrate as claimed in claim 1, claim 1, wherein the oxide layer is formed of at least one selected from the group consisting of lithium oxide (I)/Li₂O, beryllium oxide (II)/BeO, boron oxide (II)/B₂O₃, sodium oxide (I)/Na₂O, magnesium oxide (II)/MgO, aluminum oxide (III)/Al₂O₃, silicon oxide (IV)/SiO₂, phosphorus oxide (V)/P₄O₁₀, phosphorus oxide (IV)/PO₂, potassium oxide (I)/K₂O, calcium oxide (II)/CaO, scandium oxide (III)/Sc₂O₃, titanium oxide (IV)TiO₂, titanium oxide (III, IV)/Ti₃O₅, titanium oxide (III)/Ti₂O₃, titanium oxide (II)/TiO, vanadium oxide (V)N₂O₅, vanadium oxide (IV)/VO₂, vanadium oxide (III)/V₂O₃, vanadium oxide (II)/VO, chromium oxide (II)/CrO, chromium oxide (II,III)/Cr₃O₄, chromium oxide (III)/Cr₂O₃, manganese oxide (IV)/MnO₂, manganese oxide (III)/Mn₂O₃, manganese oxide (II,III)/Mn₃O₄, manganese oxide (II)/MnO, iron oxide (III)/Fe₂O₃, iron oxide (II)/FeO, iron oxide (II,III)/Fe₃O₄, cobalt oxide (II,III)/Co₃O₄, cobalt oxide (II)/CoO, nickel oxide (II)/NiO, copper oxide (II)/CuO, copper oxide (I)/Cu₂O, zinc oxide (II)/ZnO, gallium oxide (III)/Ga₂O₃, germanium oxide (IV)/GeO₂, arsenic oxide(III)/As₂O₃, selenium oxide (IV)/SeO₂, rubidium oxide (IV)/RuO₂, strontium oxide (II)/SrO, yttrium oxide (III)/Y₂O₃, zirconium oxide (IV)/ZrO₂, niobium oxide (V)/Nb₂O₅, niobium oxide (IV)/NbO₂, niobium oxide (II)/NbO, molybdenum oxide (VI)/MoO₃, molybdenum oxide (IV)/MoO₂, ruthenium oxide (VI)/RuO₃, ruthenium oxide (VIII)/RuO₄, ruthenium oxide (IV)/RuO₂, rhodium oxide (III)/Rh₂O₃, palladium oxide (II)/PdO, silver oxide (I)/Ag₂O, cadmium oxide (II)/CdO, indium oxide (III)/In₂O₃, tin oxide (IV)/SnO₂, antimony oxide (III)/Sb₂O₃, tellurium oxide (IV)/TeO₂, barium oxide (II)/BaO, cerium oxide (IV)/CeO₂, cerium oxide (III)/Ce₂O₃, praseodymium oxide (III)/Pr₂O₃, neodymium oxide (III)/Nd₂O₃, samarium oxide (III)/Sm₂O₃, europium oxide (III)/Eu₂O₃, gadolinium oxide (III)/Gd₂O₃, terbium oxide (III)/Tb₂O₃, dysprosium oxide (III)/Dy₂O₃, hafnium oxide (IV)/HfO₂, tantalum oxide (V)/Ta₂O₅, tungsten oxide (VI)/WO₃, tungsten oxide (IV)/WO₂, rhenium oxide (IV)/ReO₂, osmium oxide (IV)/OsO₂, iridium oxide (IV)/IrO₂, mercury oxide (I)/Hg₂O, lead oxide (IV)/PbO₂, lead oxide (II,III)/Pb₃O₄, lead oxide (II)/PbO, bismuth oxide (III)/Bi₂O₃, thorium oxide(IV)/ThO₂, and uranium oxide (IV)/UO₂.

6. The substrate as claimed in claim 1, wherein the semiconductor or metal layer is formed of at least one selected from the group consisting of boron (B), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), germanium (Ge), zirconium (Zr), niobium (Nb), molybdenum (Mo), ruthenium (Ru), palladium (Pd), silver (Ag), hafnium (Hf), tantalum (Ta), tungsten (W), rhenium (Re), osmium (Os), iridium (Ir), bismuth (Bi), gallium arsenide (GaAs), indium phophide (InP), indium antimonide (InSb), GaN (gallium nitride), AlN (aluminum nitride), and silicon carbide (SiC).

7. A semiconductor element manufactured with the substrate as claimed in claim 1.

8.-19. (canceled)
